(19) United States
(12) Patent Application Publication
(10) Pub. No.: US 2008/0224313 A1
(43) Pub. Date: Sep. 18, 2008

(54) Method for forming a seed layer for damascene copper wiring, and semiconductor wafer with damascene copper wiring formed using the method

(76) Inventors: Atsushi Yabe, Kitaibaraki-shi (JP); Junnosuke Sekiguchi, Kitaibaraki-shi (JP); Toru Imori, Kitaibaraki-shi (JP)

Correspondence Address: FLYNN THIEL BOUTELL & TANIS, P.C., 2026 RAMBLING ROAD, KALAMAZOO, MI, 49008-1631, US

(21) Appl. No.: 12/075,745

(22) Filed: Mar. 13, 2008

(30) Foreign Application Priority Data
Mar. 14, 2007 (JP) 2007-64348

(51) Int. Cl. H01L 23/532; H01L 21/3205

(52) U.S. Cl. 257/741; 438/678; 257/E21.295; 257/E23.161

(57) ABSTRACT

A method for forming a seed layer for damascene copper wiring is provided. The method comprises the step of forming a seed layer, during damascene copper wiring formation, using an electroless plating solution comprising a water-soluble nitrogen-containing polymer and glyoxylic acid as a reducing agent, wherein the weight-average molecular weight (Mw) of the water-soluble nitrogen-containing polymer is 1,000 to less than 100,000. Preferably, the electroless plating solution further comprises phosphinic acid.

### BACKGROUND OF THE INVENTION

1. Field of the Invention

The present invention relates to a method for forming a seed layer for damascene copper wiring, in which a seed layer is formed on a mirror-surface substrate such as a semiconductor wafer, and to a semiconductor wafer in which damascene copper wiring is formed using a copper seed layer formed by the method.

2. Description of the Related Art

In conventional electroless copper plating on mirror surfaces such as semiconductor wafers, sufficient adherence of a deposited plating film has not been obtained. In conventional electroless copper plating, plating reactivity is low, and uniform plating throughout the entire surface of a substrate has been difficult. Problems currently associated with the use of electroless copper plating include, for instance, poor uniformity and/or adherence of plating when copper film is formed on a barrier metal layer such as tantalum nitride.

Formalin is normally used as a reducing agent for electroless copper plating solutions. Formalin, however, is harmful for humans and the environment, and hence in recent years the use of glyoxylic acid, which has a similar reaction mechanism, has been studied as an alternative thereto. Japanese Patent Reference No. 2002-249879A discloses an electroless copper plating solution using glyoxylic acid as a reducing agent. The electroless copper plating solution employs glyoxylic acid as a reducing agent, potassium hydroxide as a pH adjuster, and methanol or a primary amine or the like as a Cannizaro reaction inhibitor, and it is intended to provide a solution that can be used stably over long periods of time.

The inventors had already found that plating uniformity and adherence can be effectively enhanced by using, as an electroless copper plating solution employed in electroless plating copper on mirror surface substrates such as semiconductor wafers, an electroless copper plating solution characterized by containing a water-soluble nitrogen-containing polymer, and glyoxylic acid and phosphinic acid as reducing agents (International Patent Publication No. WO2005/038086). The inventors also found that, when electroless copper plating is carried out up to filling of ultra fine damascene copper wiring, moreover, the polymer penetrates only with difficulty into the inside of the pattern structures of the member to be plated when the weight-average molecular weight (Mw) of the water-soluble nitrogen-containing polymer is 100,000 or higher and Mw/Mn (Mn: number average molecular weight) is 10.0 or less, as a result of which the copper deposited on the inside surfaces of the pattern structures does not become contaminated with the polymer. Accordingly, the growth of crystal particles on the inside surfaces of the pattern structures is not inhibited, thus preventing the impairment of copper conductivity. By contrast, when electroless copper plating is carried out only for seed layer formation of damascene copper wiring, and filling is carried out by electrolytic copper plating, it is necessary to form a thin and uniform copper seed layer on mirror surface substrates and on the inside surfaces of pattern structures of a semiconductor wafer or the like, and for that purpose, to make the size of crystal grains ultra fine. Upon formation of a seed layer of damascene copper wiring using such an electroless copper plating solution in which the weight-average molecular weight (Mw) of the water-soluble nitrogen-containing polymer is 100,000 or higher and Mw/Mn (Mn: number average molecular weight) is 10.0 or less, the polymer gets into fine pattern structures only with difficulty during formation of the seed layer. As a result, small crystals fail to be obtained, and no uniform thin film having a thickness of 15 nm or less can be formed on the inside surfaces of the pattern structures.

### SUMMARY OF THE INVENTION

An object of the present invention is to provide a method for forming a seed layer for damascene copper wiring by electroless plating, wherein the plating film is thin and uniform.

As a result of diligent research, the inventors found that the plating deposition rate can be suppressed, that crystals become extremely fine, and that a thin film having a uniform thickness no greater than 15 nm can be formed on mirror surfaces and on the inside surfaces of the pattern structures of a semiconductor wafer or the like, according to the method comprising: preparing the plating solution by adding a water-soluble nitrogen-containing polymer having a small weight-average molecular weight (Mw) as an additive to an electroless copper plating solution; preparing a substrate to be plated by adhering a catalyst metal to the substrate or by forming a catalyst metal film on the outermost surface of the substrate prior to immersion in the plating solution; and, adsorbing a polymer onto the catalyst metal via nitrogen atoms by immersing the substrate in the plating solution. The inventors found also that using simultaneously glyoxylic acid and phosphinic acid as reducing agents in the electroless copper plating solution had the effect of increasing plating reactivity through the initial catalyst metal and that, as a result, uniform plating becomes possible at lower temperatures on mirror surfaces and on the inside surfaces of the pattern structures of semiconductor wafers or the like.

Specifically, the present invention is:

(1) A method for forming a seed layer for damascene copper wiring, comprising the step of forming a seed layer, during damascene copper wiring formation, by using an electroless plating solution comprising a water-soluble nitrogen-containing polymer and glyoxylic acid as a reducing agent, wherein the weight-average molecular weight (Mw) of the water-soluble nitrogen-containing polymer is 1,000 to less than 100,000.

(2) The method for forming a seed layer for damascene copper wiring according to (1), wherein the electroless copper plating solution further comprises phosphinic acid.

(3) The method for forming a seed layer for damascene copper wiring according to (1) or (2), wherein the water-soluble nitrogen-containing polymer is polyacrylamide or polyethyleneimine.

(4) A semiconductor wafer having formed thereon damascene copper wiring by using a copper seed layer manufactured in accordance with the method for forming a seed layer for damascene copper wiring according to any one of (1) to (3).

Adding a water-soluble nitrogen-containing polymer having a weight-average molecular weight (Mw) of 1,000 to less than 100,000, as an additive, to an electroless copper plating solution that contains glyoxylic acid as a reducing agent, has the effect of slowing plating deposition rate, and of affording finer crystals, so that copper can be deposited uniformly with good adherence onto mirror surfaces and into the inside of the pattern structures of a wafer or the like. Furthermore, using simultaneously glyoxylic acid and phosphinic acid as reducing agents has the effect of making plating reactivity higher than is the case when using glyoxylic acid alone, thereby making it possible to plate uniformly, at lower temperatures, mirror surfaces and the inside of the pattern structures of a wafer or the like, where plating reactions occur with more difficulty. When forming a seed layer for damascene copper wiring using such an electroless copper plating solution, therefore, the polymer penetrates into the inside of the pattern structures and allows forming in the pattern interior a uniform thin film having a thickness of 15 nm or less.

Using such an electroless copper plating solution allows forming a thin film with a uniform thickness even in fine vias and/or trenches having a linewidth of 100 nm or less. A semiconductor wafer in which damascene copper wiring is formed using such a thin film as a seed layer is thus free of defects such as voids, seams or the like.

### DETAILED DESCRIPTION OF THE PREFERRED EMBODIMENTS

Most electroless copper plating solutions comprise copper ions, a copper ion complexing agent, a reducing agent, a pH adjuster and the like. The electroless copper plating solution of the present invention further comprises, as an additive, a water-soluble nitrogen-containing polymer having a small Mw, such that the polymer is adsorbed, via the nitrogen atoms, onto the catalyst metal which has been adhered to the substrate prior to immersion in the plating solution. As a result, the plating deposition rate is suppressed and extremely fine crystals are obtained, making it thus possible to form a uniform thin film having a thickness of 15 nm or less on mirror surfaces and on the inside surfaces of the pattern structures of a wafer or the like. The effect of the present invention is not brought out when using as the additive the primary amines and secondary amines described in Japanese Patent Publication No. 2002-249879A. Furthermore, when the Mw of the water-soluble nitrogen-containing polymer is 100,000 or more, as in International Patent Publication No. WO2005/038086, the polymer does not get into the inside of fine pattern structures during formation of a seed layer for damascene wiring, and the effect of forming a uniform thin film having a thickness of 15 nm or less on the inside surfaces of the pattern structures is not brought out.

Preferably, the Mw of the water-soluble nitrogen-containing polymer ranges from 1,000 to less than 100,000, and more preferably, from 1,200 to 30,000. With a Mw smaller than 1,000 , the finer-crystal effect of the polymer fails to be achieved, while when the Mw is equal to or greater than 100,000, the polymer does not penetrate into the inside of fine pattern structures of a wafer for damascene wiring during formation of a seed layer for damascene wiring, failing to bring about the effect of forming a uniform thin film having a thickness of 15 nm or less on the inside surfaces of the pattern structures.

Examples of the water-soluble nitrogen-containing polymer added as an additive to the electroless copper plating solution include, for instance, polyacrylamide, polyethyleneimine, polyvinylpyrrolidone, polyvinylpyridine, polyacrylonitrile, polyvinylcarbazole, polyvinylpyrrolidinone or the like. Particularly effective among these are polyacrylamide and polyethyleneimine. The concentration of the water-soluble nitrogen-containing polymer in the plating solution ranges preferably from 0.0001 to 5 g/L, more preferably from 0.0005 to 1 g/L. A concentration below 0.0001 g/L fails to bring out the above effect, while a concentration beyond 5 g/L results in excessive inhibition of the plating reaction, which precludes deposition itself from taking place.

In view of the negative effect of formalin on humans and the environment, it is desirable to use glyoxylic acid as the reducing agent of the electroless copper plating solution. Although phosphinic acid does not possess reducing activity on copper, it does exhibit high reducing activity on a catalyst metal such as palladium or the like, and hence phosphinic acid is effective for increasing initial plating reactivity mediated by such a catalyst metal. Also, phosphinic acid does not comprise sodium, which is an impurity best avoided in semiconductor applications.

Glyoxylic acid and phosphinic acid are used simultaneously as more preferred reducing agents. Such a concomitant use affords higher plating reactivity than when using glyoxylic acid alone. An electroless copper plating solution is thus obtained thereby that makes it possible to plate uniformly, at lower temperatures, mirror surfaces such as a wafer, where plating reactions are less likely to occur. Higher plating reactivity allows plating to take place at a lower temperature. The lower temperature increases in turn solution stability, and facilitates achieving finer and more uniform deposited copper particles.

The concentration of glyoxylic acid in the plating solution ranges preferably from 0.005 to 0.5 mol/L, more preferably from 0.01 to 0.2 mol/L. At a concentration below 0.005 mol/L, the plating reaction does not occur, while beyond 0.5 mol/L, the plating solution becomes unstable and decomposes. The concentration of phosphinic acid in the plating solution ranges preferably from 0.001 to 0.5 mol/L, more preferably from 0.05 to 0.2 mol/L. At a concentration below 0.001 mol/L, the above effect is not seen, while beyond 0.5 mol/L the plating solution becomes unstable and decomposes.

The catalyst-imparting method for electroless copper plating is not particularly limited, but is preferably a method that involves preparing a pre-treatment agent by mixing or reacting beforehand a noble metal compound with a silane coupling agent having a functional group capable of capturing a metal, and then subjecting to a surface treatment an object to be plated using such a pre-treatment agent, as disclosed in International Patent Publication No. WO01/49898 A1; a method that involves coating a surface to be plated with a solution of a silane coupling agent having a functional group capable of capturing a metal, and applying further an organic solvent solution of a palladium compound, as disclosed in International Patent Application No. PCT/JP03/03707; or a method that involves subjecting an object to be plated to a surface treatment using a silane coupling agent having in the molecule a functional group capable of capturing a metal, thermally treating the object to be plated at a temperature not lower than 200.C, and carrying out a surface treatment using a solution comprising a noble metal compound, as disclosed in International Patent Application No. PCT/JP03/04674. Using these catalyst-imparting methods, plating adherence and homogeneity are further enhanced.

Also, a plating substrate can be plated as-is, without resorting to the above catalyst-imparting methods, when a film of a metal having catalytic properties (such as platinum, gold, silver, palladium, rhodium, ruthenium, iridium or the like) is formed by PVD, CVD or the like on the outermost surface of the plating substrate. The cleanability and wettability of the plating substrate can also be improved by subjecting the substrate to an acid treatment, an alkaline treatment, a surfactant treatment, an ultrasonic cleaning treatment or a combination of the foregoing, prior to catalyst imparting or plating.

All of the typically used copper ion sources can be employed as the copper ion source in the electroless copper plating solution of the present invention. These include, for instance, copper sulfate, copper chloride, copper nitrate or the like. Also, any ordinarily employed complexing agent can be used as a copper ion complexing agent. These include, for instance, ethylenediamine tetraacetate, tartaric acid or the like.

Other additives that can be employed include additives typically used in plating solutions, such as 2,2′-bipyridyl, polyethylene glycol, potassium ferrocyanide or the like.

The electroless copper plating solution of the present invention is preferably used at pH 10 to 14, more preferably at pH 12 to 13. Herein there can be employed any typically used pH adjuster, such as sodium hydroxide, potassium hydroxide or the like. Tetramethylammonium hydroxide may be used in semiconductor applications when alkaline metals such as sodium, potassium or the like are to be avoided.

From the standpoint of bath stability and copper deposition rate, the electroless copper plating solution of the present invention is preferably used at a bath temperature of 50 to 90.C.

In the present invention, the material to be plated is dipped in a plating bath during plating using the electroless copper plating solution. Preferably, a catalyst is imparted to the material to be plated by carrying out the above pre-treatments, or a catalyst metal film is formed beforehand on the outermost surface of the material to be plated.

The thickness of the copper seed layer manufactured in accordance with the method for forming a seed layer for damascene copper wiring of the present invention is preferably no greater than 15 nm, and more preferably of 1 to 10 nm.

A seed layer of damascene copper wiring is formed using the electroless copper plating solution of the present invention. Herein, wiring filling using such a seed layer as a conductive layer can be conducted by electrolytic copper plating or electroless copper plating. The electrolytic copper plating solution used for filling is not particularly limited, and may be of a composition ordinarily employed for damascene copper wiring filling. Herein there can be used a solution comprising copper sulfate and sulfuric acid, as major components, and chlorine, polyethylene glycol, bis(3-sulfopropyl)disodium disulfide, or a quaternary ammonium salt adduct (quaternary epichlorohydrin) of a tertiary alkylamine and polyepichlorohydrin, as minor components. As the electroless copper plating solution used for filling there can be used the plating solution for copper wiring filling disclosed in International Patent Publication No. WO2005/038086.

The thickness of the copper seed layer manufactured in accordance with the method for forming a seed layer for damascene copper wiring of the present invention yields a thin plating film having uniform thickness. The invention allows thus forming a thin seed layer of uniform thickness also in small vias and/or trenches having a linewidth of 100 nm or less, affording as a result a semiconductor wafer that is free of defects such as voids, seams or the like.

### EXAMPLES

A trench-patterned silicon wafer of 150 nm linewidth and aspect ratio 4, and having formed thereon a 50 nm-thick tantalum film by sputtering, was subjected to the plating treatments described in Examples 1 to 3 and Comparative examples 1 to 2 below. Film thickness after treatment was checked through cleaved cross section SEM observation.

### Example 1

The tantalum-coated silicon wafer was dipped for 5 minutes, at 60.C, in a plating pre-treatment agent prepared by adding an aqueous solution of palladium chloride to an aqueous solution containing 0.01 wt. of a silane coupling agent being an equimolar reaction product from imidazole and γ-glycidoxypropyltrimethoxysilane, so that the aqueous solution of palladium chloride is 50 mg/L. Thereafter, the wafer was dipped for 3 minutes, at 60.C, in a 0.3 mol/L aqueous solution of phosphinic acid, and then electroless copper plating was carried out for 1.5 minutes at 55.C. The composition of the plating solution is 0.02 mol/L of copper sulfate, 0.21 mol/L of ethylenediamine tetraacetate, 0.03 mol/L of glyoxylic acid, 0.09 mol/L of phosphinic acid, 20 mg/L of 2,2′-bipyridyl, and 500 mg/L of polyacrylamide (Mw 10,000), and pH is 12.5 (pH adjuster: potassium hydroxide). The plating film formed uniformly also on the inside surfaces of the trenches, without irregularities. Film thickness after plating was found to be 12 nm, as observed by cleaved cross section SEM. Electrolytic copper plating was then carried out at 1 A/dm² for 3 minutes (equivalent to about 660 nm) using the above plating film as a seed layer. The composition of the copper plating solution was 0.25 mol/L of copper sulfate, 2.0 mol/L of sulfuric acid, 70 mg/L of chlorine, 200 mg/L of polyethylene glycol (Mw 10,000), 30 μmol/L of bis(3-sulfopropyl)disodium disulfide and 20 μmol/L of quaternary epichlorohydrin. The result of cleaved cross section SEM observation after plating revealed that the inside of the trench pattern was wholly filled, without any defects.

### Example 2

The tantalum-coated silicon wafer was subjected to a pre-treatment in accordance with the same method as in Example 1, and then electroless copper plating was carried out at 55.C for 1.5 minutes. The composition of the plating solution is 0.02 mol/L of copper sulfate, 0.14 mol/L of ethylenediamine tetraacetate, 0.03 mol/L of glyoxylic acid, 0.09 mol/L of phosphinic acid, 20 mg/L of 2,2′-bipyridyl, and 300 mg/L of polyethyleneimine (MW 1,800), and pH is 12.5 (pH adjuster: potassium hydroxide). The plating film formed uniformly also on the inside surfaces of the trenches, without irregularities. Film thickness after plating was 15 nm, as observed by cleaved cross section SEM. Electrolytic copper plating was then carried out at 1 A/dm² for 3 minutes (equivalent to about 660 nm) using the above plating film as a seed layer. The composition of the electrolytic copper plating solution was the same as that for Example 1. The result of cleaved cross section SEM observation after plating revealed that the inside of the trench pattern was wholly filled, without any defects.

### Example 3

A tantalum-coated silicon wafer was subjected to a pre-treatment in accordance with the same method as in Example 1, and then electroless copper plating was carried out at 60.C for 5 minutes. The composition of the plating solution is 0.02 mol/L of copper sulfate, 0.14 mol/L of ethylenediamine tetraacetate, 0.05 mol/L of glyoxylic acid, 0.18 mol/L of phosphinic acid, 20 mg/L of 2,2′-bipyridyl, and 100 mg/L of polyacrylamide (Mw 1,500), and pH is 12.5 (pH adjuster: tetramethylammonium hydroxide). The plating film formed uniformly also on the inside surfaces of the trenches, without irregularities. Film thickness after plating was found to be 14 nm, as observed by cleaved cross section SEM. Electrolytic copper plating was then carried out at 1 A/dm² for 3 minutes (equivalent to about 660 nm) using the above plating film as a seed layer). The composition of the electrolytic copper plating solution was the same as that for Example 1. The result of cleaved cross section SEM observation after plating revealed that the inside of the trench pattern was wholly filled, without any defects.

### Comparative Example 1

A tantalum-coated silicon wafer was subjected to a pre-treatment in accordance with the same method as in Example 1, and then electroless copper plating was carried out at 55.C for 1 minute. The composition of the plating solution is copper 0.02 mol/L of sulfate, 0.14 mol/L of ethylenediamine tetraacetate, 0.03 mol/L of glyoxylic acid, 0.09 mol/L of phosphinic acid and 20 mg/L of 2,2′-bipyridyl, and pH is 12.5 (pH adjuster: potassium hydroxide). The plating film exhibited rough deposition overall, and was found to be uneven ranging from 15 to 30 nm as a result of cleaved cross section SEM observation. Electrolytic copper plating was then carried out at 1 A/dm² for 3 minutes (equivalent to about 660 nm) using the above plating film as a seed layer. The composition of the electrolytic copper plating solution was the same as that for Example 1. The result of cleaved cross section SEM observation after plating revealed voids in the inside of the trench pattern.

### Comparative Example 2

A tantalum-coated silicon wafer was subjected to a pre-treatment in accordance with the same method as in Example 1, and then electroless copper plating was carried out at 55° C. for 1.5 minutes. The composition of the plating solution was 0.02 mol/L of copper sulfate, 0.21 mol/L of ethylenediamine tetraacetate, 0.03 mol/L of glyoxylic acid, 0.09 mol/L of phosphinic acid, 20 mg/L of 2,2′-bipyridyl, and 300 mg/L of polyacrylamide (Mw 110,000), and pH is 12.5 (pH adjuster: potassium hydroxide). The plating film exhibited rough deposition, with an uneven film thickness ranging from 13 to 20 nm. Electrolytic copper plating was then carried out at 1 A/dm² for 3 minutes (equivalent to about 660 nm) using the above plating film as a seed layer. The composition of the electrolytic copper plating solution was the same as that for Example 1. The result of cleaved cross section SEM observation after plating revealed voids in the inside of the trench pattern.

A trench-patterned silicon wafer of 150 nm linewidth and aspect ratio 4, and having formed thereon by sputtering either a platinum or palladium film 5 nm thick, was subjected to the plating treatments described in Examples 4 to 5 and Comparative examples 3 to 4 below. Film thickness after treatment was checked through cleaved cross section SEM observation.

### Example 4

The above platinum coated silicon wafer was subjected to electroless copper plating at 55.C for 2 minutes. The composition of the plating solution is 0.02 mol/L of copper sulfate, 0.14 mol/L of ethylenediamine tetraacetate, 0.05 mol/L of glyoxylic acid, 20 mg/L of 2,2′-bipyridyl and 50 mg/L of polyacrylamide (Mw 10,000), and pH is 12.5 (pH adjuster: potassium hydroxide). The plating film formed uniformly also on the inside surfaces of the trenches, without irregularities. Film thickness after plating was found to be 6 nm, as observed by cleaved cross section SEM. Electrolytic copper plating was then carried out at 1 A/dm² for 3 minutes (equivalent to about 660 nm) using the above plating film as a seed layer. The composition of the electrolytic copper plating solution was the same as that for Example 1. The result of a cleaved cross section SEM observation after plating revealed that the inside of the trench pattern was wholly filled, without any defects.

### Example 5

The above palladium coated silicon wafer was subjected to electroless copper plating at 55.C for 3 minutes. The composition of the plating solution is 0.02 mol/L of copper sulfate, 0.21 mol/L of ethylenediamine tetraacetate, 0.05 mol/L of glyoxylic acid, 20 mg/L of 2,2′-bipyridyl and 100 mg/L of polyacrylamide (Mw 1,500), and pH is 12.5 (pH adjuster: potassium hydroxide). The plating film formed uniformly also on the inside surfaces of the trenches, without irregularities. Film thickness after plating was found to be 5 nm, as observed by cleaved cross section SEM. Electrolytic copper plating was then carried out at 1 A/dm² for 3 minutes (equivalent to about 660 nm) using the above plating film as a seed layer. The composition of the electrolytic copper plating solution was the same as that for Example 1. The result of a cleaved cross section SEM observation after plating revealed that the inside of the trench pattern was wholly filled, without any defects.

### Comparative Example 3

The above platinum coated silicon wafer was subjected to electroless copper plating at 55.C for 1 minute. The composition of the plating solution was 0.02 mol/L of copper sulfate, 0.14 mol/L of ethylenediamine tetraacetate, 0.05 mol/L of glyoxylic acid and 20 mg/L of 2,2′-bipyridyl, and pH is 12.5 (pH adjuster: potassium hydroxide). The plating film exhibited rough deposition overall, while the results of cleaved cross section SEM observation exhibited an uneven film thickness of 10 to 20 nm. Electrolytic copper plating was then carried out at 1 A/dm² for 3 minutes (equivalent to about 660 nm) using the above plating film as a seed layer. The composition of the electrolytic copper plating solution was the same as that for Example 1. The result of cleaved cross section SEM observation after plating revealed voids in the inside of the trench pattern.

### Comparative Example 4

The above palladium coated silicon wafer was subjected to electroless copper plating at 55.C for 3 minutes. The composition of the plating solution was 0.02 mol/L of copper sulfate, 0.21 mol/L of ethylenediamine tetraacetate, 0.05 mol/L of glyoxylic acid, 20 mg/L of 2,2′-bipyridyl, and 300 mg/L of polyacrylamide (Mw 110,000), and pH is 12.5 (pH adjuster: potassium hydroxide). The plating film exhibited rough deposition, with an uneven film thickness of 7 to 14 nm. Electrolytic copper plating was then carried out at 1 A/dm² for 3 minutes (equivalent to about 660 nm) using the above plating film as a seed layer. The composition of the electrolytic copper plating solution was the same as that for Example 1. The result of cleaved cross section SEM observation after plating revealed voids in the inside of the trench pattern.

1. A method for forming a seed layer for damascene copper wiring, comprising the step of forming a seed layer, during damascene copper wiring formation, by using an electroless plating solution comprising a water-soluble nitrogen-containing polymer and glyoxylic acid as a reducing agent, wherein the weight-average molecular weight (Mw) of the water-soluble nitrogen-containing polymer is 1,000 to less than 100,000.

2. The method for forming a seed layer for damascene copper wiring according to claim 1, wherein the electroless copper plating solution further comprises phosphinic acid.

3. The method for forming a seed layer for damascene copper wiring according to claim 1, wherein the water-soluble nitrogen-containing polymer is polyacrylamide or polyethyleneimine.

4. A semiconductor wafer having formed thereon damascene copper wiring by using a copper seed layer manufactured in accordance with the method for forming a seed layer for damascene copper wiring according to claim 1.

5. A semiconductor wafer having formed thereon damascene copper wiring by using a copper seed layer manufactured in accordance with the method for forming a seed layer for damascene copper wiring according to claim 3.
